(19) United States
(12) Patent Application Publication
(10) Pub. No.: US 2011/0006333 A1
(43) Pub. Date: Jan. 13, 2011

(54) LIGHT EMITTING DIODE DEVICE

(75) Inventor: Cornelis Reinder Ronda, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/918,833

(22) PCT Filed: Feb. 24, 2009
(86) PCT No.: PCT/IB09/50730

§ 371 Date: Aug. 23, 2010

(30) Foreign Application Priority Data
Feb. 28, 2008 (EP) 08102130.5

(51) Int. Cl. H01L 33/58

(52) U.S. Cl. 257/98; 257/E33.067

(57) ABSTRACT

The invention relates to a light emitting diode device comprising a light emitting layer (103) and a filter layer (105) arranged on a surface of the light emitting layer (103), the filter layer (105) being adopted to receive light from the light emitting layer, to pass light components within a predetermined angular range and not to pass light components outside the predetermined angular range.

### FIELD OF THE INVENTION

The present invention relates to light emitting diodes.

### BACKGROUND OF THE INVENTION

Light emitting diodes (LED) comprise a light emitting layer arranged on a substrate being formed by e.g. a LED chip. The light emitting layer, e.g. a line emitting phosphor layer, emits light of e.g. a certain color associated with a certain wavelength thus generating e.g. a red or green light. However, the light emitting layer may also reflect light impinging on its surface which widens an angular range of the emitted light.

Light emitting devices are described in the U.S. Pat. No. 5,813,753, the U.S. Pat. No. 5,813,752, the EP 170320 and the EP 275601. Further approaches are described in the US 2005/0243570 A1, the EP 0922305 B1, the WO 2006/031352 A2, the US 2003/0169385 A1, the U.S. Pat. No. 4,882,617, the U.S. Pat. No. 5,813,752 and the U.S. Pat. No. 5,813,753.

### SUMMARY OF THE INVENTION

It is the object of the invention to provide a light emitting diode device with improved light emitting characteristics.

This object is achieved by the features of the independent claims.

The invention is based on the finding that light emitting characteristics of a light emitting diode may be improved when arranging a filter layer on a surface of a light emitting layer. In order to improve the angular radiation characteristic, the filter layer passes only light components which are within a predetermined angular range e.g. with respect to a normal of the filter layer. The light components which are outside the predetermined angular range are not passed by the filter layer. These components may be reflected by the filter layer towards e.g. the light emitting layer.

The invention relates to a light emitting diode device comprising a light emitting layer and a filter layer arranged on a surface of the light emitting layer, the filter layer being adopted to receive light from the light emitting layer, to pass light components within a predetermined angular range and not to pass light components outside the predetermined angular range.

According to an embodiment, the predetermined angular range is a range of ±5° with respect to a normal of the filter layer or a range of ±10° with respect to the normal of the filter layer or a range of ±15° with respect to the normal of the filter layer or a range of ±20° with respect to a normal of the filter layer or a range of ±25° with respect to a normal of the filter layer. Preferably, the angular range is between 5° to 15°.

The reduced angular range can be used in projection systems, street lights, car lights or indoor car lights e.g. to adjust the desired angular light distribution, with one or more LEDs and flashes. In general, projection systems benefit from a small angular range, preferably 5° to 15°, and lighting systems profit most from a somewhat larger angular range, preferably larger than 15°. For zoom flashes, it would be advantageous to have flexible angular ranges by using a number of different interference filters.

According to an embodiment, the filter layer is arranged to suppress light components or to reflect light components towards the light emitting layer if the light components are outside the predetermined angular range.

According to an embodiment the filter layer is an interference filter.

According to an embodiment, the light emitting layer comprises phosphor, in particular a green line emitting Ln₂O₃:Er or Ln₂O₃:Ho (Ln=Sc, Y, Gd, Lu) or a red line emitting K₂M(IV)F₆:Mn, M denoting a four valent metal ion.

According to an embodiment, the filter layer is configured to suppress or to reflect or to absorb certain spectral light components to adjust a spectral characteristic of light emittable by the light emitting diode, in particular to adjust a spectral characteristic of a color point.

According to an embodiment, the filter layer comprises a plurality of sub-layers wherein reflecting indices of subsequent sub-layers are different.

According to an embodiment, the filter layer comprises a plurality of sub-layers having a thickness in a range between 0.2λ and 0.3λ, wherein λ denotes a desired emission wavelength.

According to an embodiment, the filter layer is further adapted to form a lens.

The invention further relates to a display device comprising the inventive light emitting diode device.

The invention further relates to light emitting diode flash device comprising the inventive light emitting diode device.

The invention further relates to a method for manufacturing a light emitting diode device with manufacturing a light emitting layer; and arranging a filter layer on a surface of the light emitting layer, the filter layer being adopted to receive light from the light emitting layer, to pass light components within a predetermined angular range and not to pass light components outside the predetermined angular range.

### BRIEF DESCRIPTION OF THE DRAWINGS

Further embodiments of the invention will be described with reference to the following Figures, in which:

FIG. 1 shows a light emitting diode;

FIG. 2 shows a light emitting diode; and

FIG. 3 shows optical spectra for excitation, emission and reflection of Y₂O₃:Er.

### DETAILED DESCRIPTION OF EMBODIMENTS

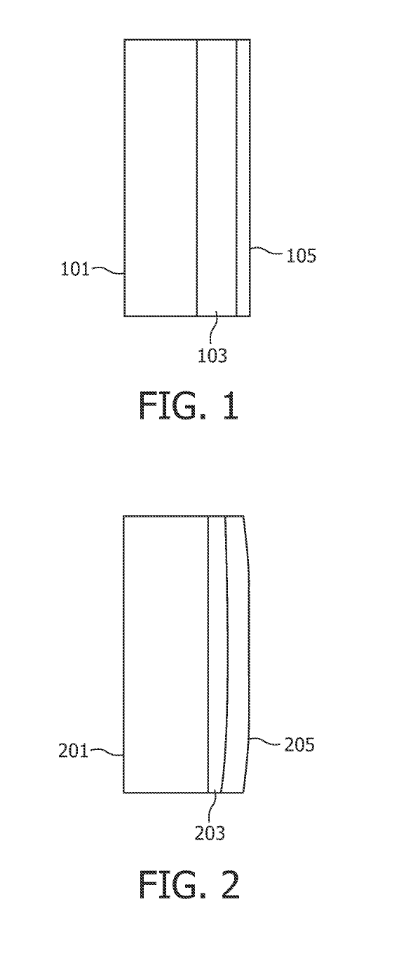

FIG. 1 shows a light emitting diode device comprising a substrate layer 101, a light emitting layer 103 arranged on a surface of the substrate layer 101 and a filter layer 105 arranged on a surface of the light emitting layer 103.

The substrate layer 101, for example a LED chip, may comprise further layers, e.g. a contact layer, a band-gap confining layer etc., which are provided to excite the light emitting layer 103. The light emitting layer 103 may be a phosphor layer or may comprise LUMIRAMIC plates.

As depicted in FIG. 1, the filter layer forming e.g. an interference filter (IF) may be used in connection with a light emitting device or in LED based systems. The interference layer 105 may further contribute to increasing a brightness and a contrast in LED based display systems, may enhance a color purity for e.g. phosphor converted LEDs, may relax LED binning issues associated with white light emitting phosphor converted LEDs or may provide a zoom function in e.g. LED flashes.

According to an embodiment, the light emitting layer 103 may comprise phosphor powder layers and/or LUMIRAMIC plates. Furthermore, the interference filter may also have a curved shape, e.g. a convex or a concave shape to process a lens function as depicted in FIG. 2.

The LED device shown in FIG. 2 has a substrate 201, e.g. a LED chip, having e.g. the characteristics of the substrate 101, a light emitting layer 203 having e.g. the characteristics of the light emitting layer 103 and a filter layer 205 having e.g. the characteristics of the filter layer 105 of FIG. 1.

Furthermore, a surface of the light emitting layer may have e.g. a convex or a concave shape wherein the filter layer 205 may have a surface following the shape of the surface of the light emitting layer 203. A top surface of the interference layer 205 may also be curved, e.g. convex or concave, to form a lens.

For example, the light emitting layer 103 and 203 may comprise green and/or red line emitting phosphor, by way of example, wherein, when using line emitters, the light output gain is increased. Furthermore, the use of line emitting phosphor reduces chromatic aberration which may be induced by optical components in the optical system. In order to provide a green line emitting phosphor, e.g. for application in phosphor conversed LEDs, e.g. Ln₂O₃:Er or Ln₂O₃:Ho (Ln=Sc, Y, Gd, Lu) may be used. In order to provide red line emitting phosphor, e.g. K₂M(IV)F₆:Mn, denoting a four-violent metal ion, may be used. Blue primaries may, however, also be employed in order to obtain more light yield in e.g. a forward direction. As far as broad-band emitters are concerned, the optical gain may be reduced but may however, still be significant. In such cases, the filter layer 105 or 205 forming e.g. interference filters may contribute to obtaining more saturated colors, for example to enlarging a color gamut. As the case may be, the interference filter according to the invention may enhance the contrast when e.g. used in display systems.

Referring again to the filter layers 105 and 205 disclosed in FIGS. 1 and 2, a light reflected back onto the reflective light emitting layer 103 or 203 or the substrate 101, 201 may be scattered so that a component of the light may pass through the respective filter layer 105 or 205. In this way, an angle at which the light leaves the LED device may be reduced which enables smaller optics and a higher light output in a desired direction.

The filter layer forming e.g. an interference filter may introduce multiple reflections of light components arriving at the interference filter within or outside a certain angular range whereas the interference filter may be transparent with respect to a fraction of the light generated by the substrate forming e.g. a LED and/or by the light emitting layer on a top of the substrate 101 when arriving at the interference filter within an angular range differing from the above outlined range.

Furthermore, the filter layer may be employed to correct small deviations of e.g. a central wavelength of e.g. a blue LED in e.g. white light emitting LED alarms. By suppressing a part of the emission generated by the light emitting layer also corrections of the color point of the LED light are possible. Moreover, the inventive approach may also be used to realize a zoom flash wherein the interference filter may be inserted in the optical pathway.

Furthermore, the filter layer may be used in combination with LUMIRAMIC plates which also may comprise a phosphor powder layer.

The filter layers shown in FIG. 1 or 2 may consist of a number of layers wherein succeeding layers may have different reflection indices. For example, a first layer may have a first reflecting index, a second layer following the first layer may have a second reflecting index which has a lower or higher reflecting index and so forth, so that, alternately, the reflecting indices are reduced or increased. Furthermore, the layers may be formed such that they do not absorb light. Furthermore, the filter layers may comprise or may consist of SiO₂ and/or TiO₂. However, other materials can also be used. The number of layers may vary and may amount to 20 in case of e.g. line emitters or may amount to an increased number, e.g. 40, in the case of broad-band emitters. The number of layers may also be dependent upon a difference in excitation wavelength of a light generated by the LED chip 101 or 201 and/or the emission wavelength of the light generated by the light emitting layer 103 or 203. The optical thickness of the filter layers, nd, n denoting the refractive index, d denoting a physical index, may be between 0.2λ and 0.3λ, λ denoting a desired central wavelength of the emitted light.

The filter layers may further be manufactured independently by e.g. sputtering or upon a basis of a gas phase on e.g. a piece of glass or plastic or silicon which may be applied to the powder layer or to the LUMIRAMIC plate. However, the filter layer may also be directly applied to LUMIRAMIC plates. Preferably, the filter layers 105 or 205 directly contact to a luminescent structure formed e.g. by the light emitting layers 103 and 203.

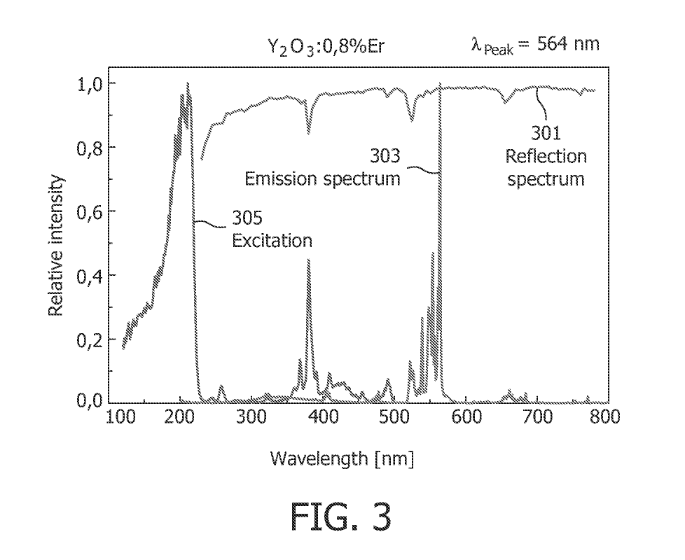

FIG. 3 shows optical spectra resulting when employing e.g. Y₂O₃:Er in a filter layer in the case of λ_{Peak}=564 nm and Y₂O₃:0.8%Er. In particular, FIG. 3 shows a curve of a reflection spectrum 301, an emission spectrum 303 and an excitation spectrum 305 with respects to a relative intensity over wavelength in nanometers.

1. A light emitting diode device, comprising:
a light emitting layer; and
an interference filter layer arranged on a surface of the light emitting layer, the interference filter layer being configured to receive light from the light emitting layer, and to pass light only within a predetermined angular range.

2. The light emitting diode device according to claim 1, the predetermined angular range being a range of ±5° with respect to a normal of the interference filter layer.

3. The light emitting diode device according to claim 1, the interference filter layer being arranged to suppress or to absorb or to reflect light components towards the light emitting layer if the light components are outside the predetermined angular range.

4. (canceled)

5. The light emitting diode device according to claim 1, the light emitting layer comprising a green line emitting phosphor Ln₂O₃:Er or Ln₂O₃:Ho (Ln=Sc, Y, Gd, Lu) or a red line emitting phosphor K₂M(IV)F₆:Mn, M denoting a four valent metal ion.

6. The light emitting diode device according to claim 1, wherein the interference filter layer is configured to adjust a spectral characteristic of light emittable by the light emitting diode.

7. The light emitting diode device according to claim 1, the interference filter layer comprising a plurality of sub-layers wherein reflecting indices of subsequent sub-layers are different.

8. The light emitting diode device according to claim 1, the interference-filter layer comprising a plurality of sub-layers having a thickness in a range between 0.2λ and 0.3λ, wherein λ denotes a desired emission wavelength.

9. The light emitting diode device according to claim 1, the interference filter layer being further adapted to form a lens.

10-13. (canceled)

14. The light emitting diode device according to claim 1, wherein the predetermined angular range is a range of ±15° with respect to the normal of the interference filter layer.

15. The light emitting diode device according to claim 1, wherein the predetermined angular range is a range of ±25° with respect to the normal of the interference filter layer.

16. The light emitting diode device according to claim 1, wherein the light emitting layer comprises phosphor.
